(19) United States
(12) Patent Application Publication
(10) Pub. No.: US 2025/0271319 A1
(43) Pub. Date: Aug. 28, 2025

(54) SEMICONDUCTOR PACKAGE

(71) Applicant: FUJI ELECTRIC CO., LTD., Kawasaki-shi (JP)

(72) Inventor: Hirofumi KATO, Matsumoto-city (JP)

(73) Assignee: FUJI ELECTRIC CO., LTD., Kawasaki-shi (JP)

(21) Appl. No.: 19/004,053

(22) Filed: Dec. 27, 2024

(30) Foreign Application Priority Data
Feb. 28, 2024 (JP) 2024-028219

(51) Int. Cl. G01L 19/00; G01L 19/14; H01L 23/31; H01L 23/495

(52) U.S. Cl. CPC G01L 19/0038; G01L 19/0084; G01L 19/143; H01L 23/3121; H01L 23/495

(57) ABSTRACT

A semiconductor package for detecting a pressure of a pressure medium flowing through a pipe. The semiconductor package includes: a case body having a pressure detection chamber; a pressure sensor chip housed in the pressure detection chamber and configured to convert a pressure applied thereto into an electrical signal; a lead frame insert-molded in the case body and electrically connected to the pressure sensor chip; and a pressure intake part having a first end protruding externally from a bottom of the case body, and a second end spatially connected to the pipe. The case body has a channel that extends from the first end of the pressure intake part and passes through a vicinity of the lead frame, to thereby guide the pressure medium from the first end of the pressure intake part through the channel to the pressure detection chamber, to apply the pressure to the pressure sensor chip.

### CROSS REFERENCE TO RELATED APPLICATIONS

This application is based upon and claims the benefit of priority of the prior Japanese Patent Application No. 2024-028219, filed on Feb. 28, 2024, the entire contents of which are incorporated herein by reference.

### BACKGROUND OF THE INVENTION

1. Field of the Invention Embodiments of the disclosure relate to a semiconductor package.

2. Description of the Related Art

International Publication No. WO 2017/212800 describes a technology that is a pressure sensor used to measure intake pressure or exhaust pressure of an internal combustion engine and has, in an outer case: a pressure measuring chamber into which a gas to be measured is fed, a sensor chip facing the pressure measuring chamber, a sensor supporting member having a supporting surface that supports the sensor chip, a temperature maintaining chamber facing a back surface (surface opposite to the supporting surface) of the sensor supporting member, and a gas channel coupling the temperature maintaining chamber and the pressure measuring chamber, the gas to be measured is fed into the temperature maintaining chamber from the pressure measuring chamber via the gas channel and thereby maintains the temperature of the sensor chip from both sides thereof, whereby condensation is suppressed around the sensor chip.

### SUMMARY OF THE INVENTION

According to an embodiment of the present disclosure, a semiconductor package for detecting a pressure of a pressure medium flowing through a pipe, the semiconductor package includes: a case body having a pressure detection chamber; a pressure sensor chip housed in the pressure detection chamber and configured to convert a pressure applied thereto into an electrical signal; a lead frame insert-molded in the case body and electrically connected to the pressure sensor chip; and a pressure intake part having: a first end protruding externally from a bottom of the case body, and a second end spatially connected to the pipe. The case body has a channel formed in the bottom thereof coupling the pressure detection chamber and the pressure intake part, the channel extending from the first end of the pressure intake part and passing through a vicinity of the lead frame, to thereby guide the pressure medium from the first end of the pressure intake part to the pressure detection chamber, such that the pressure medium applies the pressure to the pressure sensor chip in the pressure detection chamber.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view schematically depicting a structure of a semiconductor package according to a first embodiment.

FIG. 2 is a plan view schematically depicting a layout when an inside of a case body depicted in FIG. 1 is viewed from a cover body.

FIG. 3 is a cross-sectional view schematically depicting a structure of a semiconductor package according to a second embodiment.

FIG. 4 is a cross-sectional view schematically depicting a structure of a semiconductor package of a reference example.

FIG. 5 is a plan view schematically depicting a layout when an inside of a case body depicted in FIG. 4 is viewed from a cover body.

### DETAILED DESCRIPTION OF THE INVENTION

First, problems associated with the conventional technology are discussed. In International Publication No. WO 2017/212800, only a space bordered by a cover of the outer case can be heated and a temperature of a connector pin functioning as a heat sink for externally dissipating heat around the sensor chip is lower than a temperature of components in the outer case. Thus, in a vicinity of a connector between the connector pin and a connector terminal of the sensor supporting member, vapor contained in the gas to be measured is naturally cooled, generating condensate in the pressure measuring chamber. This condensate may corrode wiring and/or the connector terminal of the sensor supporting member, causing disconnection and/or short-circuit.

An outline of an embodiment of the present disclosure is described. (1) A semiconductor package according to an embodiment of the disclosure is a semiconductor package for detecting pressure of a gas flowing through a pipe and is as follows. A case body has a pressure detection chamber to which a pressure medium is sent. A pressure sensor chip is housed in the pressure detection chamber and is configured to convert pressure applied by the pressure medium into an electrical signal. A lead frame is insert molded to the case body and is electrically connected to the pressure sensor chip. A pressure intake part protrudes externally from a bottom of the case body and is spatially connected to the pipe. The gas, which constitutes the pressure medium, flows into the pressure intake part from the pipe. The pressure intake part has a closed end closed by the bottom of the case body and an open end spatially connected to the pipe. Inside the bottom of the case body, a channel coupling the pressure detection chamber, and the pressure intake part is formed passing through a vicinity of the lead frame from the closed end of the pressure intake part to the pressure detection chamber.

According to the disclosure above, the lead frame may be actively heated. As a result, the temperature of the lead frame may be made higher than the temperature of the pressure sensor chip and thus, even when vapor is contained in the pressure medium, condensation may be suppressed in a vicinity of metal members forming an electrical connector between the lead frame and the pressure sensor chip.

(2) Further, in the semiconductor package according to the disclosure, in (1) above, the case body has a space different from the pressure detection chamber and the channel may pass through the space, from the closed end of the pressure intake part to the pressure detection chamber.

According to the disclosure above, the space of the case body, different from the pressure detection chamber may be used as a space for naturally cooling the pressure medium or may be used for heat transfer to the lead frame.

(3) Further, in the semiconductor package according to the disclosure, in (2) above, the channel may include a first channel that passes through the vicinity of the lead frame and couples the pressure intake part and the space, and a second channel that couples the space and the pressure detection chamber.

According to the disclosure above, heat from the pressure medium that flows into the space of the case body, different from the pressure detection chamber is dissipated to the outside via an outer wall (side surface and top) of the case body thereby facilitating cooling of the pressure medium naturally. As a result, the amount of vapor contained in the pressure medium decreases enroute to the pressure detection chamber and thus, condensation in the pressure detection chamber may be suppressed.

(4) Further, in the semiconductor package according to the disclosure, in (2) or (3) above, the space may be bordered by the top of the case body. According to the disclosure above, in the space of the case body,

different from the pressure detection chamber, heat may be dissipated from the pressure medium to the outside via the top of the case body.

(5) Further, in the semiconductor package according to the disclosure, in (3) above, the second channel may be formed near the side surface of the case body.

According to the disclosure above, in the second channel, heat may be dissipated from the pressure medium to the outside via the side surface of the case body.

(6) Further, in the semiconductor package according to the disclosure, in (1) above, the space is formed inside the bottom of the case body, in the vicinity of the lead frame. The channel may include the first channel that couples the pressure intake part and the space, and the second channel that couples the space and the pressure detection chamber.

According to the disclosure above, the lead frame may be actively heated by the pressure medium that flows into the space of the case body, different from the pressure detection chamber.

(7) Further, in the semiconductor package according to the disclosure, in (6) above, the space may face the lead frame in a direction orthogonal to the bottom of the case body.

According to the disclosure above, heating of the lead frame by the pressure medium that flows into the space of the case body, different from the pressure detection chamber, is facilitated.

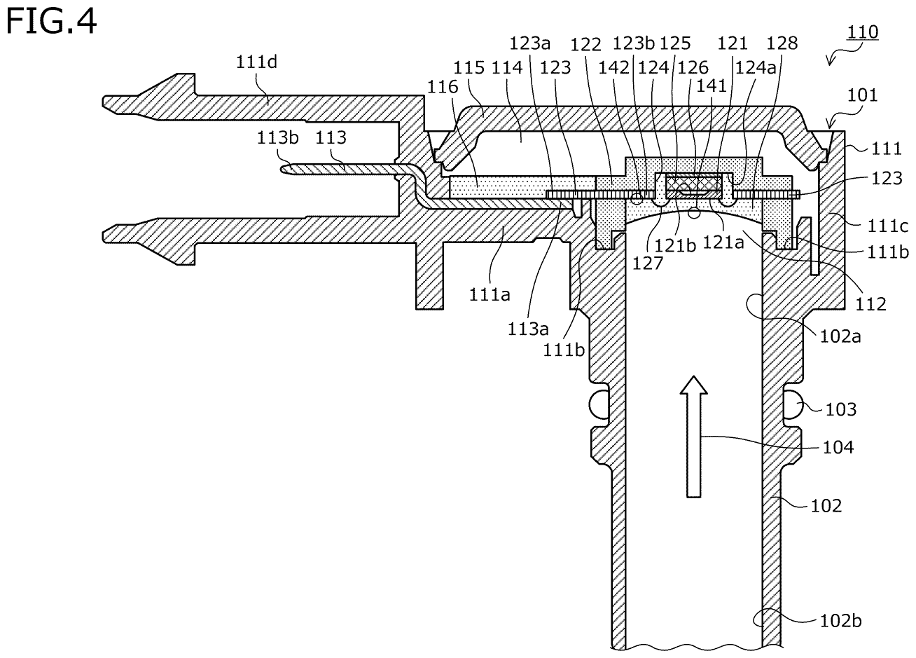

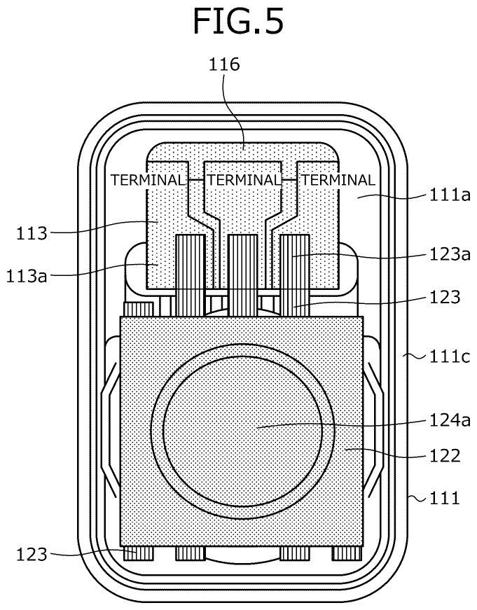

Findings underlying the present disclosure are discussed. A structure of an on-board automotive sensor package for measuring the pressure of exhaust of an internal combustion engine (engine) is described as a semiconductor package of a reference example. FIG. 4 is a cross-sectional view schematically depicting the structure of the semiconductor package of the reference example. FIG. 5 is a plan view schematically depicting a layout when an inside of a case body depicted in FIG. 4 is viewed from a cover body. A semiconductor package 110 of the reference example depicted in FIGS. 4 and 5 has a pressure sensor 101 and a pressure intake part 102 and is an on-board automotive sensor package installed to exhaust system piping (exhaust pipe, not depicted) of the engine. The pressure sensor 101 is equipped with a pressure sensor chip 121 mounted in a pressure detection chamber 112 inside a case body 111.

The pressure intake part 102 is a resin pipe (piping made of resin) integrally molded with the case body 111 and connects the pressure detection chamber 112 and the exhaust pipe. The pressure intake part 102 is a channel for a pressure medium 104 that is sent to the pressure detection chamber 112. A first open end 102a of the pressure intake part 102 is connected to the pressure detection chamber 112 at a bottom (side facing the exhaust pipe) 111a of the case body 111. A second open end 102b of the pressure intake part 102 is inserted into an opening formed in the exhaust pipe of the engine, whereby the semiconductor package 110 is directly attached to the exhaust pipe. The pressure intake part 102 connects the pressure detection chamber 112 and the exhaust pipe spatially in a straight line over a shortest distance therebetween.

The case body 111 is a resin molded product in which a lead frame 113 is insert molded. The case body 111 has, in a cross-sectional view, a substantially concave shape opened in one portion and the opened portion is covered by a cover body 115. A space (space bordered by an inner wall (the bottom 111a and sidewalls) of the case body 111 and a cover body 115 (top)) inside the case body 111 is spatially isolated from the pressure detection chamber 112 and a wiring chamber 114 by a housing container body 122. The pressure detection chamber 112 is spatially connected to the exhaust pipe linearly by the pressure intake part 102. The wiring chamber 114 is an enclosed space shielded from the outside air by the case body 111 and the cover body 115 and shielded from the pressure medium 104 by the housing container body 122.

The lead frame 113 is provided for each predetermined external connection. A first end 113a of the lead frame 113 is exposed in a space inside the case body 111 while a second end 113b thereof protrudes in a connecting portion 111d of the case body 111, from a side surface (surface substantially orthogonal to the bottom 111a) 111c of the case body 111. Inside the case body 111, the housing container body 122 is disposed so as to block the first open end 102a of the pressure intake part 102. The housing container body 122 has a substantially concave shape opened in one portion in a cross-sectional view, the opened portion facing the pressure intake part 102 and being supported by a supporting portion 111b of the bottom 111a of the case body 111.

A space (space bordered by an inner wall of the housing container body 122) inside the housing container body 122 constitutes the pressure detection chamber 112. The housing container body 122 spatially separates the pressure detection chamber 112 and another space (a space outside the housing container body 122, hereinafter, wiring chamber) 114 inside the case body 111. The first ends 113a, 123a of the lead frames 113, 123 are connected to each other in the wiring chamber 114. As described, the pressure medium 104 does not flow into the wiring chamber 114 and thus, configuration may be such that portions of the lead frames 113, 123 exposed in the wiring chamber 114 are not encapsulated by an encapsulant 116.

The housing container body 122 is a resin molded product in which the lead frame 123 is insert molded. A first end 123a of the lead frame 123 is exposed in the wiring chamber 114 while a second end 123b thereof is exposed in the pressure detection chamber 112. Inside the housing container body 122, a recess (hereinafter, sensor mounting portion) 124 that houses the pressure sensor chip 121 is formed. The pressure sensor chip 121 is die-bonded to a bottom 124a of the sensor mounting portion 124, via a pedestal member 125 and an adhesive layer 126, and is electrically connected to the second end 123b of the lead frame 123 by a bonding layer 127.

The pressure sensor chip 121 is a semiconductor integrated circuit (IC) employing a piezoresistive method that utilizes the piezoresistive effect of a diffused resistor formed in a silicon (Si) semiconductor, the pressure sensor chip 121 being a pressure-sensitive surface type semiconductor integrated circuit (IC) having a gauge surface (circuit surface where a strain gauge is provided) that is a pressure detecting surface that detects pressure of the pressure medium 104. The pressure sensor chip 121 has a diaphragm 121a that faces the first open end 102a of the pressure intake part 102, and a back surface recess 121b that is blocked by the pedestal member 125. The pressure sensor chip 121, the bonding layer 127, and the second end 123b of the lead frame 123 are encapsulated by an encapsulant 128 that is a gel type.

Operation of the semiconductor package 110 of the reference example is described. When the engine is running, combustion gas generated in the cylinders of the engine during a combustion and expansion process of the engine is discharged out of the automotive vehicle through the exhaust pipe as exhaust gas during the exhaust stroke. At this time, a portion of the exhaust gas flows into the pressure intake part 102 from the exhaust pipe and is sent to the pressure detection chamber 112 of the pressure sensor 101 as the pressure medium 104. Via the encapsulant 128, the diaphragm 121a of the pressure sensor chip 121 is distorted by pressure from by the pressure medium 104 and the pressure sensor 101 outputs an electrical signal corresponding to the distortion to an external circuit via the lead frames 123, 113.

Airtightness of the pressure intake part 102 and the exhaust pipe is increased by an O-ring 103 that blocks a gap between the pressure intake part 102 and the exhaust pipe; the pressure medium 104 that flows into the pressure intake part 102 from the exhaust pipe does not leak outside, reaches the pressure detection chamber 112, and is sent to the pressure sensor chip 121. A path of the pressure medium 104 from the exhaust pipe to the pressure detection chamber 112 is always spatially connected and no member is provided so as to shield the pressure sensor chip 121 from the pressure medium 104. Thus, the thermal energy generated during the combustion process of the engine is transferred from the pressure medium 104 to the pressure sensor chip 121 substantially without being dissipated.

The pressure detection chamber 112 and the exhaust pipe are spatially connected in a straight line by the pressure intake part 102 and thus, the pressure medium 104 reaches the pressure sensor chip 121 substantially without being cooled. The pressure sensor chip 121 receives the most thermal energy from the pressure medium 104 and becomes the hottest among the components of the pressure sensor 101. On the other hand, the lead frame 113 is formed of a metallic material and has high thermal conductivity. The lead frame 113 is connected to an external circuit and functions as a heat sink that receives the heat generated in the pressure sensor chip 121 from the lead frame 123 and releases the heat to the outside and thus, cools more easily than other components of the pressure sensor 101.

The temperature of the lead frame 123 is lower than the temperature of the pressure sensor chip 121 and thus, the temperature of the encapsulant 128, at a portion 142 thereof encapsulating the lead frame 123 is lower than a portion (portion where the pressure medium 104 is closest to the pressure sensor chip 121) 141 thereof encapsulating the pressure sensor chip 121. The pressure medium 104 contains vapor that is generated during the combustion of fuel (gasoline, etc.); the vapor penetrates the encapsulant 128, is naturally cooled by the portion 142 of the encapsulant 128 having a relatively low temperature, whereby the vapor is condensed and discharged as condensate. Thus, the condensate may cause corrosion of the lead frame 123 and short circuit or disconnection of the bonding layer 127.

Suppressing condensation in a pressure detection chamber is one issue solved by the present embodiments.

A semiconductor package according to an embodiment of the present disclosure is described in detail with reference to the accompanying drawings. In the description below and the accompanying drawings, main components that are identical are given the same reference numerals and are not repeatedly described.

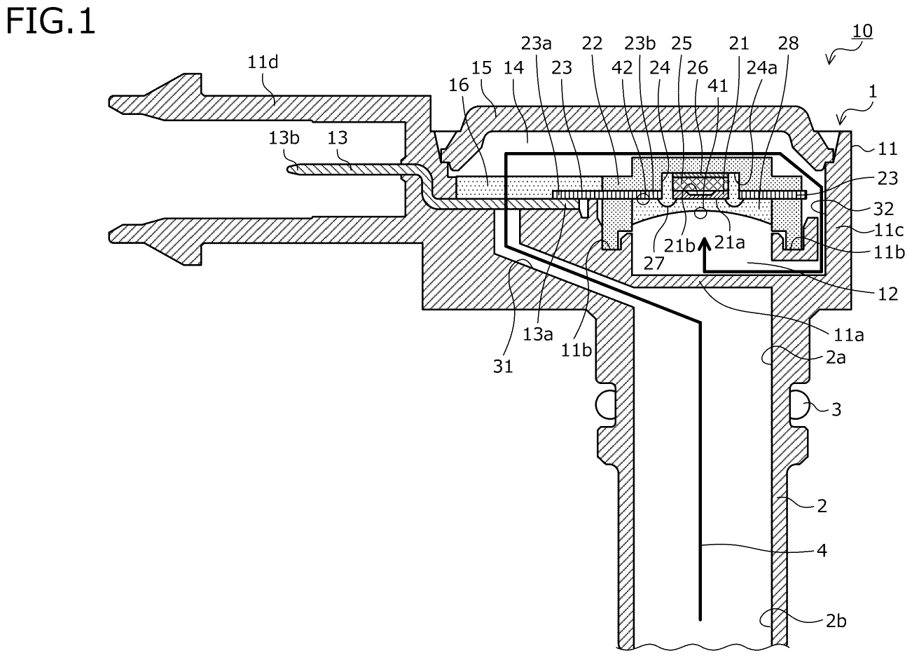

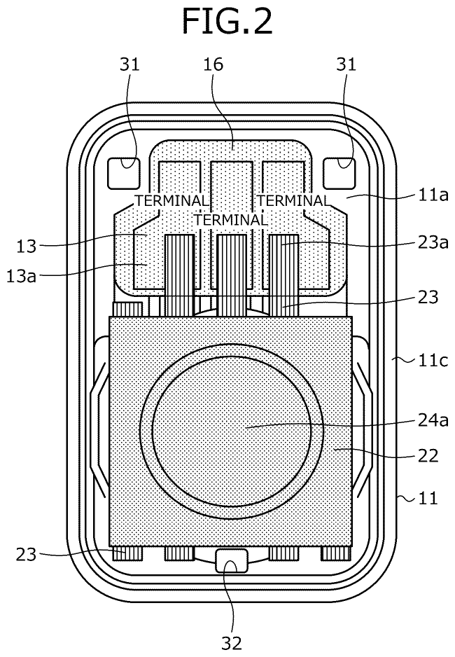

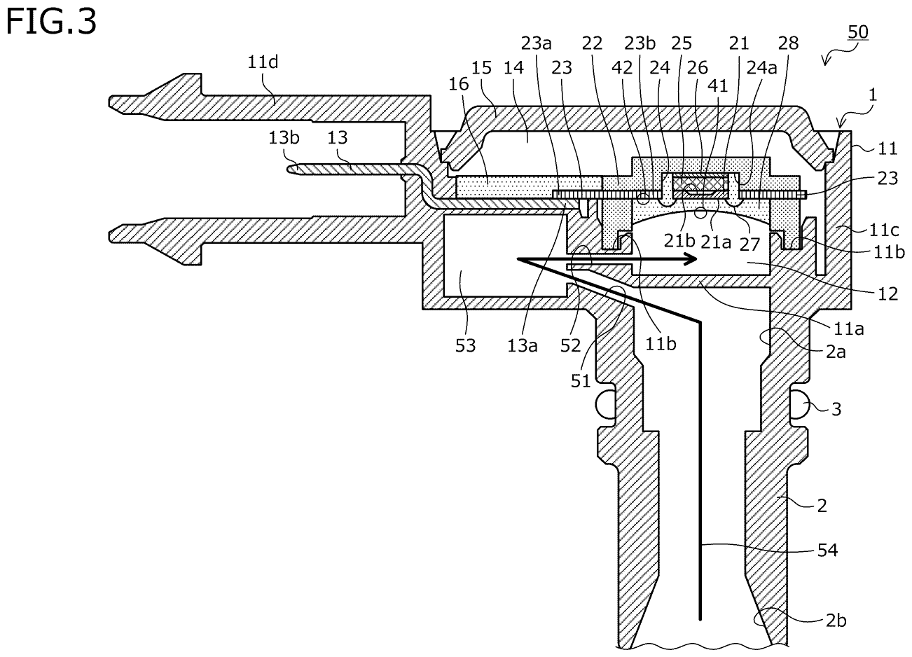

A semiconductor package according to a first embodiment solving the problems above is described. FIG. 1 is a cross-sectional view schematically depicting a structure of a semiconductor package according to a first embodiment. In FIG. 1, flow of a pressure medium 4 is indicated by a bold arrow (similarly in FIG. 3). FIG. 2 is a plan view schematically depicting a layout when an inside of a case body depicted in FIG. 1 is viewed from a cover body. FIG. 2 depicts a bottom (a bottom 11a of the case body 11 and a top of a pressure detection chamber 12) of the wiring chamber 14 of the case body 11, and members disposed at the bottom of the wiring chamber 14. In FIG. 2, a connecting portion 11d for external connection of the case body 11 is not depicted.

A semiconductor package 10 according to the first embodiment depicted in FIGS. 1 and 2 includes a pressure sensor 1 and a pressure intake part 2 and is an on-board automotive sensor package that is for measuring pressure and installed to piping of an internal combustion engine (engine). The semiconductor package 10, for example, is installed to exhaust system piping (exhaust pipe, not depicted) of the engine. The semiconductor package 10 is useful when the pressure medium 4 is a gas having a higher temperature and a higher humidity than the temperature and humidity of outside air and is particularly suitable for measuring the pressure of exhaust gas (exhaust pressure measurement). The semiconductor package 10 is not limited to exhaust pipes of automotive vehicles and may be installed to other piping (for example, turbocharger piping) through which a gas having a higher temperature and a higher humidity than the temperature and humidity of outside air.

The pressure sensor 1 is mounted to a pressure sensor chip (semiconductor substrate) 21 in the pressure detection chamber 12 inside the case body 11, and outputs, as an electrical signal, pressure detected by the pressure sensor chip 21, the electrical signal being output to an external circuit (not depicted) via a lead frame 13. The pressure sensor 1 is supplied with voltage from a power source IC (not depicted) of an engine control unit (ECU) for controlling the engine or a power source IC (not depicted) of an electronic control unit (ECU) for controlling the driving performance, safety, and environmental friendliness of the automotive vehicle and is controlled by the ECU.

The case body 11 (including the connecting portion 11d), a later-described housing container body 22, the pressure intake part 2, and the exhaust pipe, for example, are formed of a high-performance resin having excellent heat resistance, mechanical strength, durability (chemical resistance, abrasion resistance), non-combustibility, electrical insulation, processability, etc., a so-called super engineering plastic such as polyphenylene sulfide (PPS). Thus, as compared to an instance in which these components of the exhaust system of the engine are formed of a metal, the suppression of corrosion due to the exhaust gas and a reduction in the weight of the exhaust system of the engine may be realized. The lead frames 13, 23, for example, contain phosphor bronze as a main material.

The case body 11 is a resin molded product in which the lead frame 13 is insert molded and, for example, has a substantially rectangular shape in a plan view. The case body 11 has a partially open and substantially concave shape in a cross-sectional view, and the partially open part is blocked by a cover body 15. A space (space bordered by an inner wall (the bottom 11a and side surfaces) and a top (the cover body 15) of the case body 11) inside the case body 11 is divided into the pressure detection chamber 12 and the wiring chamber 14 by the later-described housing container body 22. The pressure detection chamber 12 and the wiring chamber 14 are shielded from the outside air by the case body 11. The pressure detection chamber 12 is spatially connected to the pressure intake part 2 via the wiring chamber 14 and is not directly connected to the pressure intake part 2.

The wiring chamber 14 is a space (space outside the housing container body 22) between the top of the pressure detection chamber 12 and the cover body 15 inside the case body 11. The lead frames 13, 23 are exposed in the wiring chamber 14. Inside the wiring chamber 14, first ends 13a, 23a of the lead frames 13, 23 are connected to each other. Preferably, all portions of the lead frame 13 and the lead frame 23 connected to the lead frame 13 exposed in the wiring chamber 14 may be encapsulated by a general gel-type encapsulant 16. The encapsulant 16 functions as a cap film ensuring airtightness of the lead frames 13, 23 inside the wiring chamber 14.

A supporting portion 11b that supports the housing container body 22 is provided at an inner wall at the bottom (portion facing the exhaust pipe) 11a of the case body 11. The supporting portion 11b is a concave portion formed at the inner wall of the bottom 11a of the case body 11. An end of a sidewall of an opening of the housing container body 22 is fitted into the supporting portion 11b as described hereinafter. Further, first and second channels 31, 32 are provided at the bottom 11a of the case body 11. The first and second channels 31, 32 are channels of the pressure medium 4 sent to the pressure detection chamber 12 and spatially connect the pressure intake part 2 and the pressure detection chamber 12. Shapes in a plan view, widths, and the number of the first and second channels 31, 32 may be suitably set.

In particular, the first channel 31 is a through hole penetrating through the bottom 11a of the case body 11, from a first end (closed end) 2a of the pressure intake part 2 to the wiring chamber 14, in a vicinity of the lead frame 13 (i.e., vicinity of the encapsulant 16) and couples the wiring chamber 14 and the pressure intake part 2. Heat dissipated from the pressure medium 4 flowing through the first channel 3 may actively heat the lead frames 13, 23. The pressure medium 4 flowing through the pressure intake part 2 may be first flowed to the vicinity of the lead frame 13, and a path from the closed end 2a of the pressure intake part 2 to the wiring chamber 14 may be suitably set. The first channel 31 may meander inside the bottom 11a of the case body 11 so as to face the lead frame 13.

The second channel 32 is a through hole meandering inside the bottom 11a of the case body 11, from the wiring chamber 14 to the pressure detection chamber 12 and couples the wiring chamber 14 and the pressure detection chamber 12. Inside the wiring chamber 14, heat from the pressure medium 4 is dissipated to the outside air via the cover body 15 of the case body 11 and the pressure medium 4 is cooled naturally. The second channel 32 may be provided in a vicinity of a sidewall (portion orthogonal to the bottom 11a) 11c of the case body 11. In the second channel 32, heat is easily dissipated from the pressure medium 4 to the outside air via the sidewall 11c of the case body 11, and the pressure medium 4 is further cooled naturally while traveling from the wiring chamber 14 to the pressure detection chamber 12.

By design, the first and second channels 31, 32 are formed in a margin within the bottom 11a of the case body 11, where members cannot be disposed. For example, as depicted in FIG. 2, the case body 11 has, in a plan view, a substantially rectangular shape that almost exactly fits necessary members (such as the housing container body 22 and the lead frames 13 and 23) on the inner wall of the bottom 11a. Thus, the margin of the bottom 11a of the case body 11, for example, is assumed to be a gap between the sidewall 11c of the case body 11 and members inside the case body 11, a space between an inner wall of the sidewall 11c of the case body 11 and the lead frames 13, 23, a gap between the lead frames 23 that are adjacent to each other and not encapsulated, and the like.

The connecting portion 11d for external connection of the case body 11 protrudes outside from the sidewall 11c of the case body 11. The connecting portion 11d of the case body 11 is a plug that mates with a socket of a connector portion of cables (harness, not depicted) for wiring within the engine compartment, and has therein the lead frame 13 (three in FIG. 2) for each predetermined external connection as plug pins (terminals). The external connections of the lead frame 13, for example, are wiring connections for supplying voltage from the ECU's power supply IC to the pressure sensor chip 21, wiring connections for inputting control signals from the ECU to the pressure sensor chip 21, and wiring connections for external output from the pressure sensor chip 21.

A thickness of the bottom 11a of the case body 11 is suitably set, thereby enabling a length of the first and second channels 31, 32 to be suitably set. Further, the thickness of the bottom 11a of the case body 11 is suitably set, thereby enabling warming of the pressure detection chamber 12 by the pressure medium 4 in the pressure intake part 2 to be suppressed even when the pressure intake part 2 faces the pressure detection chamber 12 via the bottom 11a of the case body 11. The case body 11 may be an existing integrally molded product in which the first and second channels 31 and 32 are formed and may have nearly a same shape as the existing integrally molded product. Thus, existing internal members may be used for the lead frame 13 and the case body 11.

The first end 13a of the lead frame 13 is exposed in the wiring chamber 14 while the second end 13b thereof protrudes in the connecting portion 11d of the case body 11, from the sidewall 11c of the case body 11. Inside the case body 11, the housing container body 22 is disposed on the inner wall of the bottom 11a of the case body 11. The housing container body 22 has, in a cross-sectional view, a substantially concave shape that is partially opened. The housing container body 22 is supported by the bottom 11a of the case body 11 with the partially open portion (side opposite the bottom) thereof facing the bottom 11a of the case body 11 and the end of the sidewall (portion substantially orthogonal to the bottom) of the opening fitting into the supporting portion 11b of the bottom 11a of the case body 11.

A space (space bordered by the inner wall of the housing container body 22) inside the housing container body 22 constitutes the pressure detection chamber 12. The housing container body 22 is a resin molded product in which the lead frame 23 is insert molded. The first end 23a of the lead frame 23 is exposed in the wiring chamber 14 while the second end 23b is exposed in the pressure detection chamber 12. The lead frame 23 is one of multiple lead frames 23 and in the wiring chamber 14, a different one of the lead frames 23 is connected to each of the lead frames 13 of the case body 11. Inside the pressure detection chamber 12, a concave portion (sensor mounting portion) 24 in which the pressure sensor chip 21 is housed so as to face the pressure detection chamber 12 is formed at the top of the pressure detection chamber 12 (inner wall of the housing container body 22, at a bottom thereof). The sensor mounting portion 24, for example, has a substantially circular shape in a plan view.

The pressure sensor chip 21 is a semiconductor IC employing a piezoresistive method that utilizes the piezoresistive effect of a diffused resistor (gauge resistor) formed in a silicon (Si) semiconductor, the semiconductor IC having a gauge surface (circuit surface where a strain gauge is provided) that is a pressure-sensitive surface that senses the pressure medium 4, which is an object to be detected. The pressure sensor chip 21 has a center portion and an outer peripheral portion and a diaphragm structure in which the center portion is etched from a back of the pressure sensor chip 21 thereby forming a recess 21b whereby a thickness of the pressure sensor chip 21 is thinner in the center portion than in the outer peripheral portion. The pressure sensor chip 21 includes a diaphragm (pressure-sensitive portion) 21a that bends in response to pressure, the strain gauge (not depicted), and computing circuity (not depicted) for amplifying and compensating output of the strain gauge. The diaphragm 21a, for example, has a substantially circular shape in a plan view.

The strain gauge contains a material (Si semiconductor) having a piezoresistive effect and is configured by multiple gauge resistors (not depicted) connected to a bridge, the strain gauge being provided on a front side of the pressure sensor chip 21, facing the diaphragm 21a. The gauge resistors are each electrically connected to the lead frame 13 via a bonding layer 27 and a surface electrode (not depicted) on a front surface of the pressure sensor chip 21. Distortion of the diaphragm 21a occurring when pressure from the pressure medium 4 is received, is converted by the strain gauge into an electrical signal of a magnitude proportional to the pressure (potential difference occurring among the bridge of the gauge resistors in proportion to the pressure), and the electrical signal is led out to the external circuit via the lead frame 13.

The outer peripheral portion of the pressure sensor chip 21, at a back surface thereof, for example, is electrostatically bonded (anode bonded) to a first surface of a pedestal member 25 so that the recess 21b at the back surface of the pressure sensor chip 21 is sealed by the pedestal member 25. A second surface of the pedestal member 25 is die-bonded (fixed) to a floor 24a of the sensor mounting portion 24 via an adhesive layer 26. The pressure sensor chip 21 and the pedestal member 25 are disposed apart from sidewalls of the sensor mounting portion 24. The pedestal member 25, for example, is a glass substrate formed of heat-resistant glass. The pressure sensor chip 21, the bonding layer 27, and the second end 23b of the lead frame 23 are encapsulated by a general, gel-type encapsulant 28.

The pressure intake part 2 is a hollow, cylindrical resin pipe (piping made of resin) having a diameter smaller than a diameter of the exhaust pipe and couples the first channel 31 and the exhaust pipe. The pressure intake part 2 is integrally molded with the case body 11 and protrudes externally from the bottom 11a of the case body 11. The pressure intake part 2 is spatially connected to the pressure detection chamber 12, via the first channel 31, the wiring chamber 14, and the second channel 32. A first end (hereinafter, closed end) 2a of the pressure intake part 2 is closed by the bottom 11a of the case body 11 so as to be not directly connected to the pressure detection chamber 12. The closed end 2a of the pressure intake part 2 may face the pressure detection chamber 12 via the bottom 11a of the case body 11.

A second end (open end) 2b of the pressure intake part 2 is inserted into a mounting hole formed at a curved surface (side surface) of the exhaust pipe, whereby the semiconductor package 10 is directly installed to the exhaust pipe. Exhaust gas flowing through the exhaust pipe when the engine is running (when the automotive vehicle is traveling, idling, etc.) flows into the pressure intake part 2 as the pressure medium 4. The pressure intake part 2 is a channel for the pressure medium 4 that is sent to the pressure detection chamber 12; the pressure intake part 2 is always spatially connected to the exhaust pipe. A length of the pressure intake part 2 is short and the pressure sensor 1 and the exhaust pipe are positioned relatively close to each other. The pressure intake part 2, from a portion thereof facing the pressure detection chamber 12 bordered by the bottom 11a of the case body 11, extends linearly toward the exhaust pipe.

The exhaust pipe is a hollow, cylindrical resin pipe through which the exhaust gas (combustion gas) flows during the exhaust stroke of the engine, the exhaust pipe coupling cylinders (not depicted) of the engine and the outside (outside of the automotive vehicle). When the engine is running, the exhaust gas constantly flows into the pressure intake part 2 from the exhaust pipe, passes through the pressure intake part 2, the first channel 31, the wiring chamber 14, and the second channel 32, to be sent to the pressure detection chamber 12 as the pressure medium 4. An O-ring 3 is provided on the outer periphery of the pressure intake part 2 to seal a gap between the exhaust pipe and the pressure intake part 2. The O-ring 3 ensures the airtightness between the exhaust pipe and the pressure intake part 2.

Operation of the semiconductor package 10 according to the first embodiment is described. When the engine is running, air is taken into the engine and during a process of exhausting combustion gas that is generated in the cylinders of the engine during a combustion/expansion process of the engine, the combustion gas is exhausted as exhaust gas outside of the automotive vehicle, through the exhaust pipe. A portion of the exhaust gas flows from the exhaust pipe into the pressure intake part 2 as the pressure medium 4, and from the pressure intake part 2, reaches the pressure detection chamber 12 by passing through the first channel 31 of the bottom 11a of the case body 11, the wiring chamber 14 of the case body 11, and the second channel 32 of the bottom 11a of the case body 11.

Heat is dissipated from the pressure medium 4 that flows into the first channel 31, the heat being dissipated to the lead frame 13 through a thin resin part (the bottom 11a of the case body 11) between the first channel 31 and the lead frame 13. As a result, the lead frame 13, and the lead frame 23 connected to the lead frame 13 can be actively heated. Thereafter, the pressure medium 4 flows into the wiring chamber 14 and the second channel 32, and heat is dissipated from the pressure medium 4 to the outside air through the cover body 15 (and further from the sidewall 11c of the case body 11), whereby the pressure medium 4 is naturally cooled.

The pressure medium 4 that has been naturally cooled flows into the pressure detection chamber 12 and reaches the pressure sensor chip 21. Thus, in the pressure detection chamber 12, a temperature of the encapsulant 28 in a portion 42 thereof encapsulating the lead frame 23 is higher than in a portion (portion where the pressure medium 4 comes closest to the pressure sensor chip 21) 41 thereof encapsulating the pressure sensor chip 21. As a result, vapor contained in the pressure medium 4 may be suppressed from forming a condensate at the portion 42 encapsulating the lead frame 23, whereby corrosion of the lead frame 23, short circuit and/or disconnection of the bonding layer 27 may be suppressed.

Further, the pressure medium 4 is naturally cooled and thus, vapor contained in the pressure medium 4 is condensed and discharged as condensate. As described, the pressure medium 4 is naturally cooled in the wiring chamber 14 (and further in the second channel 32) and thus, vapor contained in the pressure medium 4 is condensed while the pressure medium 4 is enroute to the pressure detection chamber 12 thereby enabling the amount of vapor contained in the pressure medium 4 to be reduced (dehumidified). Vapor contained in the pressure medium 4 has been reduced when the pressure medium 4 flows into the pressure detection chamber 12 and thus, condensation in the pressure detection chamber 12 may be suppressed.

The pressure medium 4 that reaches the pressure detection chamber 12 is transmitted to the pressure sensor chip 21. A resistance value of the strain gauge changes in response to pressure applied to the diaphragm 21a of the pressure sensor chip 21 by the pressure medium 4 and the pressure sensor 1 outputs the change in the resistance value of the strain gauge as an electrical signal to an external circuit. While the response speed of the pressure sensor 1 decreases the longer is the path of the pressure medium 4, airtightness of the path of the pressure medium 4 from the exhaust pipe to the pressure detection chamber 12 is maintained and thus, measurement accuracy of the pressure sensor 1 is about a same as the measurement accuracy of the pressure sensor 101 (refer to FIGS. 4 and 5) of the reference example.

As described, according to the first embodiment, the pressure intake part and the pressure detection chamber are not directly connected but are spatially connected via the first and second channels formed inside the bottom of the case body of the pressure sensor. The first channel is formed in a vicinity of the lead frame, which is insert molded in the case body. The exhaust gas, which has a high temperature and a high humidity and flows from the exhaust pipe into the pressure intake part, flows as the pressure medium into the first channel from the closed end of the pressure intake part, passes a vicinity of the lead frame, and is sent to the pressure detection chamber. The lead frame may be actively heated by the pressure medium flowing through the first channel. As a result, the temperature of the lead frame may be raised to be higher than the temperature of the pressure sensor chip.

Further, the pressure medium is naturally cooled through a space (the wiring chamber and the second channel) different from the pressure detection chamber inside the case body before reaching the pressure detection chamber and the amount of vapor contained in the pressure medium is reduced. The naturally cooled pressure medium flows into the pressure detection chamber and is sent to the pressure sensor chip, whereby in the pressure detection chamber, the temperature of the encapsulant at a portion of the encapsulant encapsulating the lead frame is higher than the temperature of a portion of the encapsulant encapsulating the pressure sensor chip. As a result, condensation at the portion encapsulating the lead frame may be suppressed and thus, corrosion of the lead frame, short circuit and disconnection of the bonding layer may be suppressed. Further, the pressure medium is naturally cooled, whereby the amount of vapor contained in the pressure medium is reduced thereby enabling condensation in the pressure detection chamber to be suppressed.

A semiconductor package according to a second embodiment solving the problems above is described. FIG. 3 is a cross-sectional view schematically depicting a structure of the semiconductor package according to the second embodiment. A semiconductor package 50 according to the second embodiment differs from the semiconductor package 10 according to the first embodiment in that instead of the first and second channels 31, 32 (refer to FIGS. 1 and 2), first and second channels 51, 52 constituting channels of a pressure medium 54 and a space 53 for heat transfer are provided. The first and second channels 51, 52 and the space 53 for heat transfer are formed inside the bottom 11a of the case body 11, at positions close to the pressure intake part 2, the lead frame 13, and the pressure detection chamber 12.

In particular, the first channel 51 is a through hole reaching the space 53 for heat transfer from the closed end 2a of the pressure intake part 2 and couples the space 53 and the pressure intake part 2. Preferably, the first channel 51 may be formed over a shortest distance from the closed end 2a of the pressure intake part 2 to the space 53. The second channel 52 is a through hole that reaches the pressure detection chamber 12 from the space 53 for heat transfer and couples the space 53 and the pressure detection chamber 12. The second channel 52 may be formed over a shortest distance from the space 53 to the pressure detection chamber 12. The first and second channels 51 and 52 may meander through the bottom 11a of the case body 11 so as to face the lead frame 13.

The space 53 for heat transfer is formed in the bottom 11a of the case body 11, at a position close to the lead frame 13. Preferably, the space 53 for heat transfer may face the lead frame 13 (preferably, all the lead frames 13) in a direction orthogonal to the bottom 11a of the case body 11. Heat from the pressure medium 54 that flows into the space 53 from the pressure intake part 2 via the first channel 51 is dissipated to the lead frame 13 via the thin resin portion (the bottom 11a of the case body 11) between the space 53 and the lead frame 13. Thus, the lead frames 13, 23 can be actively heated by the pressure medium 54 in the space 53.

In the second embodiment, the space (space bordered by the inner wall of the case body 11 and the cover body 15) inside the case body 11 is spatially separated into the pressure detection chamber 12 and the wiring chamber 14 by the housing container body 22. The pressure detection chamber 12 and the wiring chamber 14 are shielded from the outside air by the case body 11. The pressure detection chamber 12 is spatially connected to the pressure intake part 2 via the space 53 in the bottom 11a of the case body 11 and is not directly connected to the pressure intake part 2. The wiring chamber 14 is an enclosed space shielded from the outside air by the case body 11 and the cover body 15 and shielded from the pressure medium 54 by the housing container body 22.

In other words, when the engine is running, a portion of the exhaust gas passes through the pressure intake part 2, the first channel 51, the space 53, and the second channel 52 of the bottom 11a of the case body 11 from the exhaust pipe as the pressure medium 54 and reaches the pressure detection chamber 12. Similar to the first embodiment, the lead frames 13, 23 can be actively heated by the pressure medium 54 that flows into the space 53.

Thereafter, the pressure medium 54 is naturally cooled enroute to the pressure sensor chip 21. Thus, similar to the first embodiment, in the pressure detection chamber 12, the temperature of the encapsulant 28 is higher at the portion 42 encapsulating the lead frame 23 than at the portion 41 encapsulating the pressure sensor chip 21.

As described, according to the second embodiment, even when configuration is such that the pressure medium reaches the pressure detection chamber from the pressure intake part through the heat transfer space in the bottom of the case body, the same effect as the first embodiment may be obtained.

In the foregoing, the present disclosure is not limited to the embodiments described above and may be variously modified within a range not departing from the spirit of the present disclosure.

The semiconductor package according to the present disclosure achieves an effect in that condensation may be suppressed.

As described, the semiconductor package according to the present disclosure is useful for semiconductor packages that are for measuring pressure and installed to piping and is particularly suitable in instances when installed to exhaust system piping (exhaust pipe) of an internal combustion engine (engine) to measure the pressure of exhaust gas.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor package for detecting a pressure of a pressure medium flowing through a pipe, the semiconductor package comprising:
a case body having a pressure detection chamber;
a pressure sensor chip housed in the pressure detection chamber and configured to convert a pressure applied thereto into an electrical signal;
a lead frame insert-molded in the case body and electrically connected to the pressure sensor chip; and
a pressure intake part having:
a first end protruding externally from a bottom of the case body, and
a second end spatially connected to the pipe, wherein
the case body has a channel formed in the bottom thereof coupling the pressure detection chamber and the pressure intake part, the channel extending from the first end of the pressure intake part and passing through a vicinity of the lead frame, to thereby guide the pressure medium from the first end of the pressure intake part to the pressure detection chamber, such that the pressure medium applies the pressure to the pressure sensor chip in the pressure detection chamber.

2. The semiconductor package according to claim 1, wherein
the case body has a space different from the pressure detection chamber, and
the pressure medium is guided from the first end of the pressure intake part through both the channel and the space to the pressure detection chamber.

3. The semiconductor package according to claim 2, wherein the channel includes:
a first channel passing through the vicinity of the lead frame and coupling the pressure intake part and the space, and
a second channel coupling the space and the pressure detection chamber.

4. The semiconductor package according to claim 3, wherein the space is partially formed by a top of the case body.

5. The semiconductor package according to claim 3, wherein the second channel is partially formed by a side surface of the case body.

6. The semiconductor package according to claim 2, wherein
the space is formed inside the bottom of the case body, and in the vicinity of the lead frame, and
the channel includes:
a first channel coupling the pressure intake part and the space, and
a second channel coupling the space and the pressure detection chamber.

7. The semiconductor package according to claim 6, wherein the space faces the lead frame in a direction orthogonal to the bottom of the case body.

8. The semiconductor package according to claim 1, wherein
the pressure medium is gas, and
the pipe is an engine pipe.
